(19) United States
(12) Patent Application Publication
(10) Pub. No.: US 2013/0135055 A1
(43) Pub. Date: May 30, 2013

(54) SURFACE MOUNT PIEZOELECTRIC OSCILLATOR

(71) Applicant: Nihon Dempa Kogyo Co., Ltd., Tokyo (JP)

(72) Inventor: HIDENORI HARIMA, SAITAMA (JP)

(73) Assignee: NIHON DEMPA KOGYO CO., LTD., TOKYO (JP)

(21) Appl. No.: 13/633,880

(22) Filed: Oct. 3, 2012

(30) Foreign Application Priority Data
Nov. 30, 2011 (JP) 2011-262316

(51) Int. Cl. H03B 5/36

(52) U.S. Cl. 331/116 R

(57) ABSTRACT

A surface mount piezoelectric oscillator includes a piezoelectric resonator, a mounting board, and an IC chip mounted on the mounting board. An oscillator circuit includes the IC chip and the piezoelectric resonator. The piezoelectric resonator is bonded to the mounting board with solder balls. The mounting board includes a ceramic plate. The mounting board includes connecting terminals and a wiring pattern on the one mounting board principal surface of the mounting board. The connecting terminals are connected to the terminals of the piezoelectric resonator via solder balls. The mounting board includes an intermediate layer on the one mounting board principal surface and integrally formed with the mounting board. The intermediate layer includes solder ball placement openings to position the solder balls in a center of each of the connecting terminals and an IC chip mounting opening to mount the IC chip.

### CROSS-REFERENCE TO RELATED APPLICATION

This application claims the priority benefit of Japan application serial no. 2011-262316, filed on Nov. 30, 2011. The entirety of the above-mentioned patent application is hereby incorporated by reference herein and made a part of this specification.

### BACKGROUND OF THE INVENTION

1. Field of the Invention

This disclosure relates to a piezoelectricity oscillator, and in particular, relates to a surface mount piezoelectric oscillator where a piezoelectric resonator is connected to an integrated circuit chip (IC chip) via solders or gold bumps. The IC chip consists of an oscillator circuit together with the piezoelectric resonator.

2. Description of Related Art

Portable information terminals, such as mobile phones and so-called tablets, or vehicle electronic equipments have become popular. At the same time, most of electronic components mounted on these pieces of equipment have employed downsized and low-profile components called surface mounting devices. The surface mounting device includes a surface of a component body (a facing surface to the mounting board) with a flat connecting terminal (a surface mount terminal). The surface mounting device is oppositely connected to a terminal pad (also called a land or land pattern) on a surface of the mounting board via the solder film.

A general piezoelectric material includes crystal. Here, a description will be given of a crystal unit as the piezoelectric resonator and a crystal controlled oscillator as the piezoelectricity oscillator with a crystal unit. However, the present invention is not limited to these piezoelectricity oscillators. The present invention is similarly applicable to a component related to a piezoelectric component such as a SAW filter (surface acoustic wave filter), a laminated circuit component, and various discrete components.

As an exemplary crystal controlled oscillator described here is downsized and lightweight. Accordingly, the crystal controlled oscillator is mounted on a surface of various pieces of electronic equipment such as mobile equipment as a frequency reference source or a time reference source. The crystal controlled oscillator is used alone or included in another circuit. Nowadays, there is a need for consideration for solder cracking and strong soldering connection in electronic equipment such as vehicle equipment where an impact occurs and temperature environment considerably changes. The solder cracking is caused by difference in thermal expansion coefficient due to temporal change (heat cycle) or stress variation such as substrate warpage due to an external force. The strong soldering connection prevents damage on a board or a main body of the component.

FIG. 9 is a schematic sectional view illustrating an exemplary configuration of the crystal controlled oscillator as an example of the surface mount piezoelectric oscillator according to a conventional technique. A crystal controlled oscillator 1 includes a crystal unit 2 and a mounting board 3 with an IC chip 33. The crystal unit 2 includes a container main body that includes a bottom wall layer 21 and a frame wall layer 22, which are preferred to employ ceramic material. The container main body houses a crystal element 24 in a recess surrounded by the frame wall layer 22. The crystal element 24 has excitation electrodes (not shown) on both surfaces of its crystal slice. Extraction electrodes (not shown) extending from the excitation electrodes to end edges are secured to a pair of crystal holding terminals 26 with a conductive adhesive 25. The pair of crystal holding terminals 26 are disposed on an inside bottom surface (one principal surface) of the recess.

The recess housing the crystal element 24 is hermetically sealed by a lid body 23 formed of a metal plate, thus forming a crystal unit 2. The lid body 23 employs a blank, a ceramic plate, a hard resin plate, or a similar plate. The bottom wall layer 21 has terminals 27 which are external terminals on an outside bottom surface (the other principal surface) to be connected to the mounting board 3 with the IC chip 33.

In this example, the mounting board 3 with the IC chip 33 employs a laminated substrate formed of ceramic plates 31 and 32. The mounting board 3 is not limited to the laminated substrate, and may employ a single layer substrate. One principal surface (an IC chip mounting surface) of the mounting board 3 has a plurality of connecting terminals 36 that connect a wiring pattern to a plurality of electrode pads 35 and the terminals 27 of the crystal controlled oscillator 1. The other principal surface (the mounting surface) of the mounting board 3 has a plurality of mounting terminals 37 to be mounted on a surface of a circuit board of the electronic equipment to apply. In this example, a ground layer 38 that provides an electromagnetic shielding function is disposed between the ceramic plates 31 and 32. The ground layer 38 is connected to a ground pattern (not shown).

The IC chip 33 is secured to the electrode pads 35 via its mounting bumps 34 (such as gold bumps) by ultrasonic thermo-compression bonding or similar method.

Further, an underfill layer 39 or an adhesive layer, which is preferred to be made of epoxy resin, is filled between the IC chip 33 and the mounting board 3. The mounting board 3 with the IC chip 33 and the crystal unit 2 are secured together as follows. The terminals 27 of the crystal unit 2 are arranged corresponding to the solder balls on the connecting terminals 36. The solder balls are melted in a solder reflow process, and then the melted solders are hardened. In some oscillators, the other principal surface of the crystal unit 2 is bonded to the IC chip via an adhesive 28 such as epoxy resin. Japanese Patent Publication No. 2004-180012 discloses this kind of oscillator.

As described above, the solder balls 4 of the crystal controlled oscillator 1 are arranged on the connecting terminals 36 of the mounting board 3 with the IC chip 33, and the crystal unit 2 is temporarily secured. The reflow process melts the solder balls 4 so as to connect the connecting terminals 36 to the terminals 27 of the crystal unit 2, and then hardens the solder so as to secure both of them together.

FIGS. 10A and 10B are explanatory views where the crystal unit and the mounting board with the IC chip are connected together in the configuration of FIG. 9. FIG. 10A is a plan view illustrating an exemplary pattern of the connecting terminals on one principal surface of the mounting board 3 with the IC chip. FIG. 10B is a sectional view where the solder ball is temporarily secured to the connecting terminal 36 of the mounting board 3, and also a sectional view taken along the Y-Y′ line of FIG. 10A. FIG. 11 is a sectional view where the terminal of the crystal unit is secured with the solder ball. As illustrated in FIG. 10A, one principal surface (a surface opposite to the crystal unit) of the mounting board 3 has the wiring pattern. The wiring pattern includes the electrode pad 35 and the connecting terminals 36. The electrode pad 35 is connected to the mounting bump of the IC chip. Each of the connecting terminals 36 is connected to the terminal 27 of the crystal unit via the solder ball.

FIG. 10B illustrates the solder ball that is temporarily secured to the connecting terminal 36 of the mounting board 3, and melts in the reflow process. In the case where the solder ball 4 is not accurately disposed on the connecting terminal 36, a melted solder 40 may flow outside of the connecting terminal 36. Accordingly, hardened solder between the connecting terminal 36 and the terminal 27 of the crystal unit 2 has a solder fillet in a distorted shape as its appearance when the crystal unit 2 is connected as illustrated in FIG. 11. Further, the connecting terminal 36 and the terminal 27 of the crystal unit 2 are secured together by an insufficient amount of solder, thus the securing strength is decreased. These prevent improvement in yield of all products.

Further, in the case where solder connections in a plurality of respective portions become non-uniform, an external impact and temperature variation (temperature stress), which temporally repeats, accumulate after mounting on the electronic equipment, thus causing stress concentration on the above connected portions. This stress concentration causes imbalanced distribution of bonding strength in the connected portions between the crystal unit and the mounting board. This may cause functional failure due to separation and cracking in the bonded portion.

A need thus exists for a piezoelectricity oscillator which is not susceptible to the drawback mentioned above.

### SUMMARY OF THE INVENTION

According to an aspect of this disclosure, a surface mount piezoelectric oscillator includes a piezoelectric resonator, a mounting board, and an IC chip mounted on the mounting board. An oscillator circuit includes the IC chip and the piezoelectric resonator. The piezoelectric resonator is bonded to the mounting board with solder balls. The piezoelectric resonator includes a container main body. The container main body includes a bottom wall layer and a frame wall layer. A first principal surface of the bottom wall layer is laminated to form the frame wall layer and a recess is formed. The recess accommodates a piezoelectric oscillation piece. A lid body hermetically seals an opening end of the recess. The bottom wall layer of the container main body has terminals on a second principal surface. The terminals are connected to the mounting board. The mounting board consists of a ceramic plate. The mounting board includes connecting terminals and a wiring pattern on one mounting board principal surface of the mounting board. The one mounting board principal surface faces the piezoelectric resonator of the mounting board. The connecting terminals are connected to the terminals of the piezoelectric resonator by melting and hardening the solder balls. The wiring pattern includes electrode pads. The electrode pads are connected to mounting bumps of the IC chip. The mounting board includes an intermediate layer on the one mounting board principal surface. The intermediate layer is integrally formed with the mounting board. The intermediate layer includes solder ball placement openings to position the solder balls in a center of each of the connecting terminals and an IC chip mounting opening to mount the IC chip. The mounting board includes surface mount terminals on another mounting board principal surface. The surface mount terminals are for mounting an electronic device thereon.

### BRIEF DESCRIPTION OF THE DRAWINGS

The foregoing and additional features and characteristics of this disclosure will become more apparent from the following detailed description considered with the reference to the accompanying drawings, wherein:

FIG. 1 is an exploded sectional view illustrating a surface mount crystal controlled oscillator as a surface mount piezoelectric oscillator according to Embodiment 1 disclosed here.

FIG. 2A is a plan view illustrating a connecting terminal and an electrode pad on one mounting board principal surface of a mounting board according to Embodiment 1 disclosed here.

FIG. 2B is a plan view of an intermediate layer according to Embodiment 1 disclosed here.

FIG. 2C is a plan view illustrating an exemplary positional relationship between: the intermediate layer, the connecting terminal, and the electrode pad on one mounting board principal surface of the mounting board according to Embodiment 1 disclosed here.

FIG. 3 is a perspective view illustrating a positional relationship between the intermediate layer and the mounting board according to Embodiment 1 disclosed here.

FIG. 4A is a plan view illustrating an arrangement of the electrode pad of the mounting board and a solder ball according to Embodiment 1 disclosed here.

FIG. 4B is a partial sectional view taken along the X-X′ line of FIG. 4A.

FIG. 5 is a sectional view illustrating an exemplary positional relationship between the electrode pad of the mounting board and a solder ball according to Embodiment 1 disclosed here.

FIG. 6 is a sectional view illustrating a solder fillet formed between the electrode pad of the mounting board and a terminal of a crystal unit according to Embodiment 1 disclosed here.

FIG. 7 is an exploded sectional view illustrating a surface mount crystal controlled oscillator that is a surface mount piezoelectric oscillator according to Embodiment 2 disclosed here.

FIG. 8A is a plan view illustrating a connecting terminal and an electrode pad on one mounting board principal surface of a mounting board according to Embodiment 3 disclosed here.

FIG. 8B is a plan view of an intermediate layer according to Embodiment 3 disclosed here.

FIG. 8C is a plan view illustrating an exemplary positional relationship between: the intermediate layer, the connecting terminal, and the electrode pad on one mounting board principal surface of the mounting board according to Embodiment 3 disclosed here.

FIG. 9 is a schematic sectional view illustrating an exemplary configuration of a crystal controlled oscillator as an example of a surface mount piezoelectric oscillator according to a conventional technique disclosed here.

FIG. 10A is a plan view of a mounting board with an IC chip according to the configuration in FIG. 9 disclosed here.

FIG. 10B is a sectional view illustrating connection between a crystal unit and the mounting board with the IC chip according to the configuration of FIG. 9 disclosed here.

FIG. 11 is a sectional view illustrating the terminal of the crystal unit secured with a solder ball according to the configuration in FIG. 9 disclosed here.

### DESCRIPTION OF THE EMBODIMENTS

A first embodiment disclosed here will be explained with reference to the attached drawings. Each description will be given of embodiments in this disclosure in detail below.

### Embodiment 1

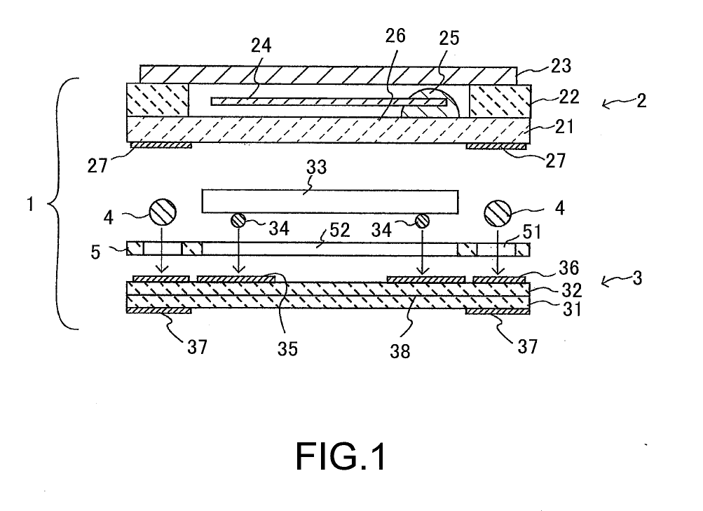

FIG. 1 is an exploded sectional view illustrating a surface mount the crystal controlled oscillator as a surface mount piezoelectric oscillator according to Embodiment 1 disclosed here. A surface mount piezoelectric oscillator which is a crystal controlled oscillator 1 according to Embodiment 1 includes a piezoelectric resonator which is a crystal unit 2 and a mounting board 3 with an IC chip 33. The crystal unit 2 has a container main body that includes a bottom wall layer 21 and a frame wall layer 22. The frame wall layer 22 surrounds a recess that houses a piezoelectric oscillation piece, herein is a crystal element 24. The crystal element 24 has excitation electrodes (not shown) on both front and back surfaces of a crystal slice. The crystal element 24 is secured to a pair of crystal holding terminals 26 with a conductive adhesive 25 via extraction electrodes (not shown), which extend from the excitation electrodes to one end edge of the crystal element 24. The pair of crystal holding terminals 26 are disposed on an inside bottom surface (the first principal surface of the bottom wall layer 21) of the recess.

The recess, which houses the crystal element 24, is hermetically sealed by a lid body 23 formed of a metal plate, thus forming the crystal unit 2. The lid body 23 may employ a blank, a ceramic plate, a hard resin plate, or a similar plate other than the metal plate. In the case where the lid body 23 formed of the metal plate is used, the lid body 23 formed of the metal plate is welded to the frame wall layer 22 by seam welding via a metal thin film similar to the lid body 23. The bottom wall layer 21 has a plurality of terminals 27 that are terminals (external terminals) on its outside bottom surface (the second principal surface of the bottom wall layer 21) to be connected to the mounting board 3 with the IC chip 33.

The mounting board 3 with the IC chip 33 employs a laminated substrate formed of ceramic plates 31 and 32. While in this example, the mounting board 3 employs the laminated substrate, the mounting board 3 may employ a single layer substrate. One mounting board principal surface (an IC chip mounting surface) of the mounting board 3 has a wiring pattern, a plurality of electrode pads 35, and a plurality of connecting terminals 36. The plurality of connecting terminals 36 are to be connected to the crystal controlled oscillator 1. The another mounting board principal surface (a mounting surface) of the mounting board 3 has a plurality of mounting terminals 37 to be mounted on a surface of a circuit board of the electronic equipment to apply. A ground layer 38, which provides an electromagnetic shielding function, is disposed between ceramic plates 31 and 32. The ground layer 38 is connected to a ground pattern (not shown) on the mounting board 3.

In Embodiment 1, an intermediate layer 5 is interposed between the crystal unit 2 and the mounting board 3. The intermediate layer 5 has a function that accurately positions solder balls 4 on the connecting terminals 36, respectively. The intermediate layer 5 also has a function as so-called solder resist that prevents melted solder of the solder balls 4 from flowing toward the wiring pattern and the electrode pads 35, which are disposed close to the connecting terminals 36 on which the solder balls 4 are disposed. The intermediate layer 5 employs a ceramic sheet similar to the mounting board 3.

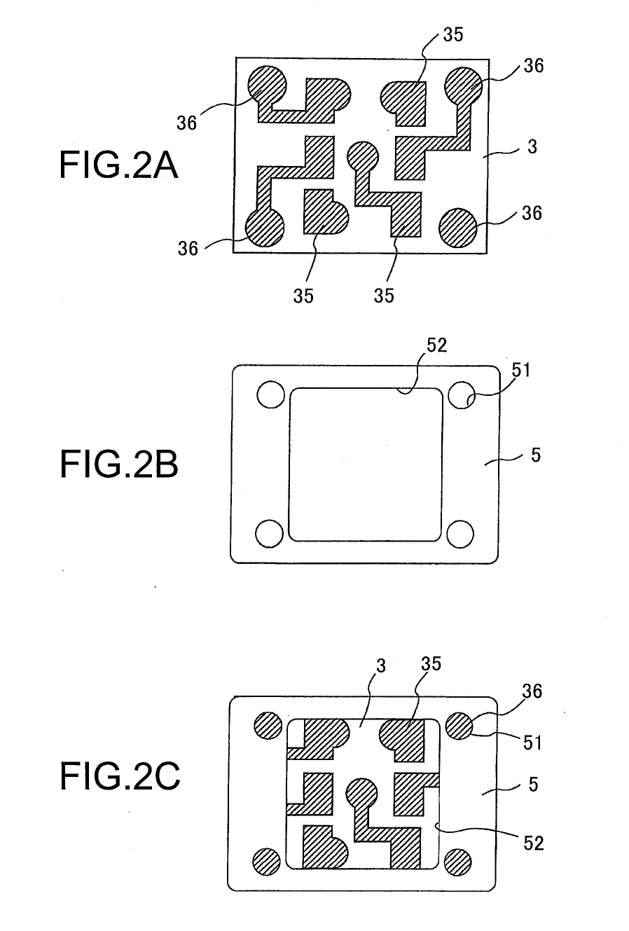

FIGS. 2A and 2B are plan views illustrating an exemplary arrangement of the intermediate layer, the connecting terminals and the electrode pads on one principal surface of the mounting board according to Embodiment 1 disclosed here. FIG. 2A is a plan view illustrating the one mounting board principal surface (a surface opposed to the crystal unit 2) of a mounting board 3. The plurality of connecting terminals 36 are formed to be connected to the terminals 27 of the crystal unit 2. The plurality of wiring patterns and electrode pads 35 are disposed close to these connecting terminals 36. These connecting terminals 36, wiring pattern, and electrode pads 35 are connected to the IC chip 33 and the mounting terminals 37 via a through-hole and a via hole (not shown) on the mounting board 3.

FIG. 2B is a plan view illustrating the intermediate layer 5. The intermediate layer 5 includes solder ball placement openings 51 at its four corners. The intermediate layer 5 includes an IC chip mounting opening 52 in the center of a region to position the IC chip 33. FIG. 2C is a plan view illustrating the mounting board 3 and the intermediate layer 5 integrated together. As illustrated in the plan view, each of the solder ball placement openings 51 of the intermediate layer 5 exposes the connecting terminal 36. The IC chip mounting opening 52 exposes the wiring pattern and the electrode pads 35.

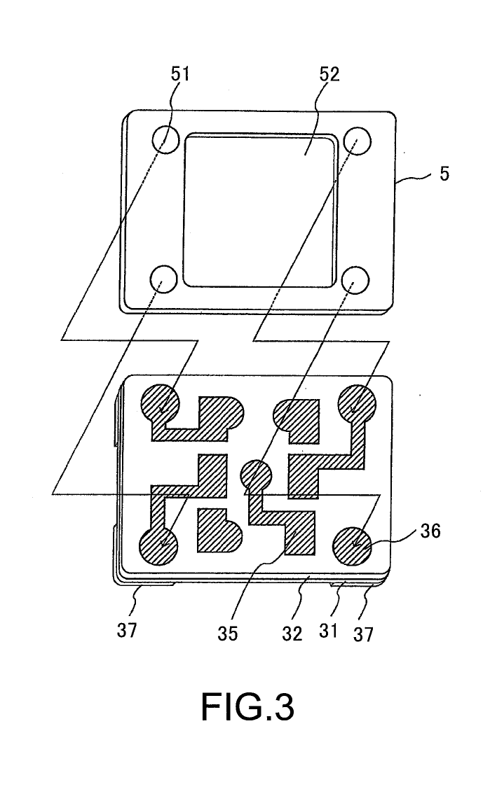

FIG. 3 is a perspective view illustrating a positional relationship between the intermediate layer and the mounting board according to Embodiment 1 disclosed here. FIG. 3 is a view illustrating more details of FIGS. 2A to 2C. The intermediate layer 5 and the mounting board 3 are laminated such that the center of each of the solder ball placement openings 51 in the intermediate layer 5 corresponds to the center of each of the connecting terminals 36.

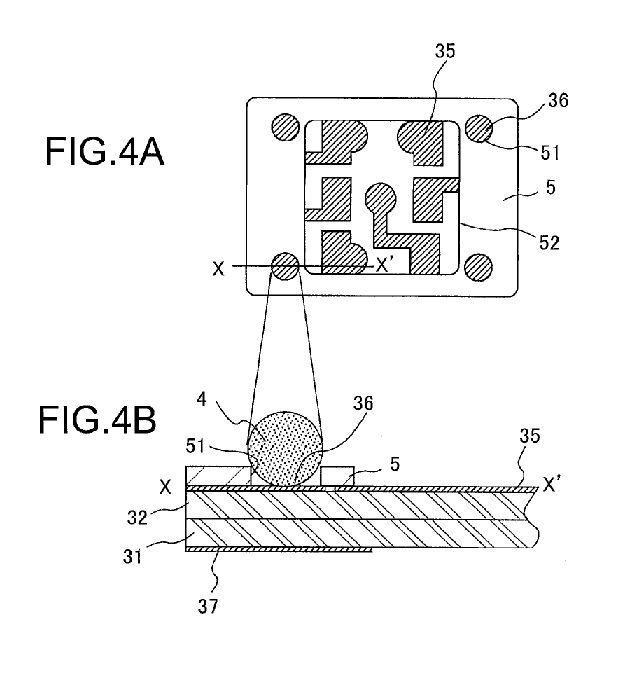

FIGS. 4A and 4B are explanatory views illustrating an arrangement of the electrode pad of the mounting board and the solder ball according to Embodiment 1 disclosed here. FIG. 4A corresponds to FIG. 2C. FIG. 4B is a partial sectional view taken along the X-X′ line of FIG. 4A. The solder ball 4 is placed in the solder ball placement opening 51 of the intermediate layer 5. The solder ball placement opening 51 has the center approximately corresponding to the center of the connecting terminal 36. Accordingly, the solder ball 4 is placed within an area of the connecting terminal 36 temporarily secured by flux (not shown) applied over the connecting terminal 36. FIG. 4B illustrates the solder ball 4 temporarily secured to the connecting terminal 36.

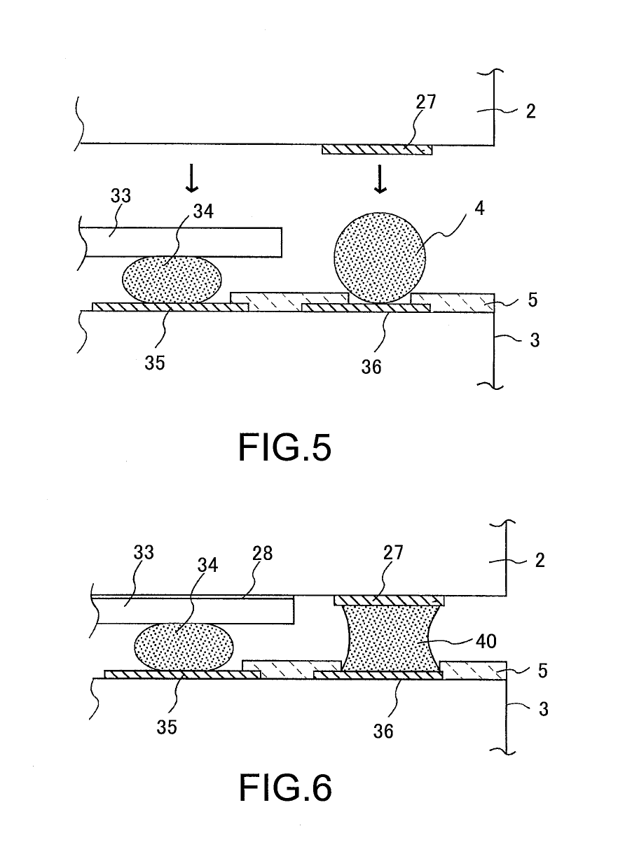

FIG. 5 is a sectional view illustrating an exemplary positional relationship between the electrode pad of the mounting board and a solder ball according to Embodiment 1 disclosed here. As illustrated in FIG. 4B, the crystal unit 2 is laminated on the mounting board 3 on which the solder ball 4 is disposed as indicated by a bold arrow (see FIG. 5). The laminated members pass through a reflow furnace, and the solder ball 4 is then melted. The solder ball is hardened after passing through the reflow furnace. FIG. 6 illustrates the hardened solder ball.

FIG. 6 is a sectional view illustrating a solder fillet formed between the electrode pad of the mounting board and the terminal of the crystal unit according to Embodiment 1 disclosed here. As illustrated in the drawing, the solder of the solder ball 4 does not flow out. Thus, a solder fillet 40 is formed to be a balanced sidewall shape between the terminal 27 of the crystal unit 2 and the connecting terminal 36.

As described above, the intermediate layer 5 includes a ceramic sheet that has a thickness thinner than a void between the crystal unit 2 and the mounting board 3 in a product. The intermediate layer 5 has the solder ball placement openings 51 in the positions corresponding to the positions of the connecting terminals 36 in the mounting board 3, and also has the opening (the IC chip mounting opening) 52 corresponding to a bump area for mounting the IC chip 33. The intermediate layer 5 is disposed on one mounting board principal surface of the mounting board 3. The intermediate layer 5 is co-fired with the mounting board 3 so as to integrate them together. The mounting board 3 is preferred to include a metal film (which is made of copper, tungsten, and similar material) as a ground layer 38 that is an electromagnetic shielding layer between the plurality of ceramic plates 31 and 32 and electromagnetically shields from the outside.

The plurality of solder ball placement openings 51 in the intermediate layer 5 controls the plurality of solder balls 4 in predetermined positions. This uniformly forms an appropriate solder fillet 40 between the terminal 27 of the crystal unit 2 and the connecting terminal 36 of the mounting board 3 after each solder ball 4 is temporarily secured, melted in the reflow process, and hardened to be secured. This prevents melted solder from flowing outside of the connecting terminal 36 of the mounting board 3, and then prevents interference to the adjacent other wiring patterns or electrode pads 35, thus reducing short-circuit failure of a product. This ensures uniform and strong connection between the crystal unit 2 and the mounting board 3, thus providing a piezoelectricity oscillator such as a crystal controlled oscillator with high reliability.

### Embodiment 2

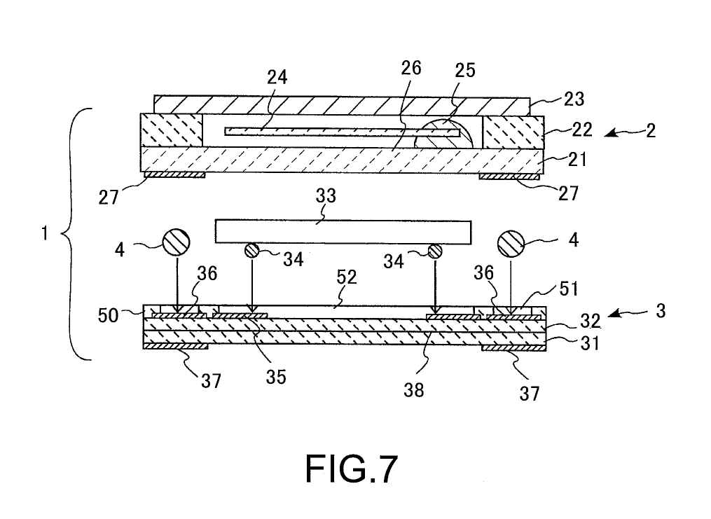

FIG. 7 is an exploded sectional view illustrating a surface mount crystal controlled oscillator 1 that is a surface mount piezoelectric oscillator according to Embodiment 2 disclosed here. The whole structure of the crystal controlled oscillator 1 is similar to that of Embodiment 1 except an intermediate layer 50, and therefore duplicative descriptions will be omitted except necessary matters.

The embodiment 2 uses an intermediate layer 50 that is a ceramic paste layer where ceramic paste is applied and fired. The ceramic paste is assumed to be slurry with appropriate viscosity where fine particle of ceramic material similar to that of the mounting board 3 is dispersed in a dispersion medium. The ceramic paste is applied by a method using screen-printing or a dispenser so as to form the solder ball placement openings 51 and the IC chip mounting opening 52 corresponding to the bump area for mounting the IC chip 33, similarly to the above description. Then, the intermediate layer 50 is co-fired with the mounting board 3 to be integrated together.

The IC chip 33 is mounted on the mounting board 3 with the intermediate layer 50. The IC chip 33 is secured to the electrode pads 35 at its mounting bumps 34 by ultrasonic thermo-compression bonding. Then, each of the solder balls 4 passes through a reflow furnace to be melted after solder ball 4 is placed in the solder ball placement opening 51, and is temporarily secured. The solder ball 4 is hardened after passing through the reflow furnace. The condition of the hardened solder ball 4 is similar to that in FIG. 6.

With Embodiment 2, the plurality of solder ball placement openings 51 in the intermediate layer 50 controls the plurality of solder balls 4 in the predetermined positions. This uniformly forms the solder fillet in a fine shape between the terminal 27 of the crystal unit 2 and the connecting terminal 36 of the mounting board 3 after the respective solder balls 4 are temporarily secured, melted to be secured in the reflow process, and then hardened. This prevents the melted solder from flowing outside of the connecting terminal 36 in the mounting board 3, and prevents the interference to the adjacent other wiring patterns or electrode pads 35, thus reducing short-circuit failure of the product. This ensures the uniform and strong connection between the crystal unit 2 and the mounting board 3, thus providing the piezoelectricity oscillator such as the crystal controlled oscillator with high reliability.

### Embodiment 3

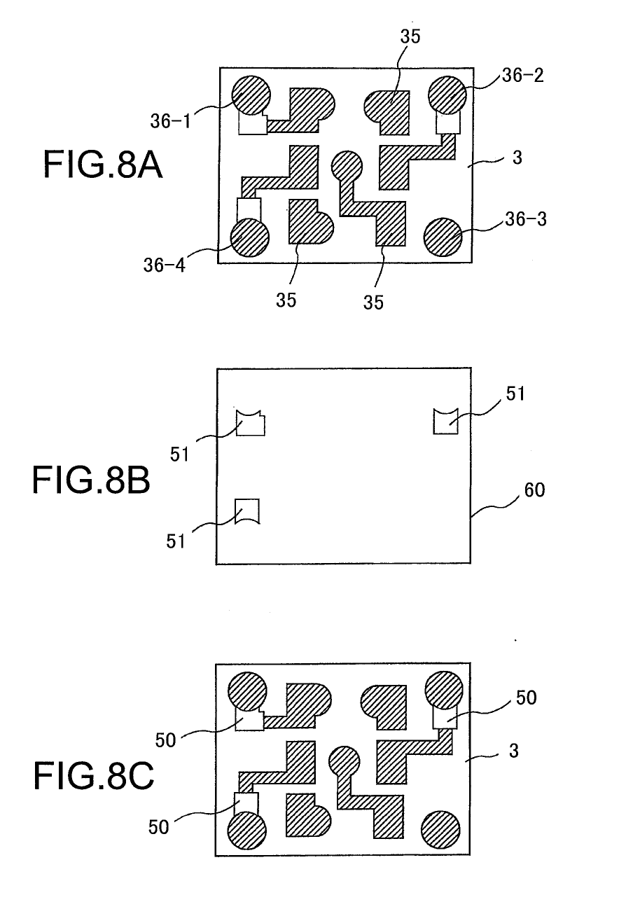

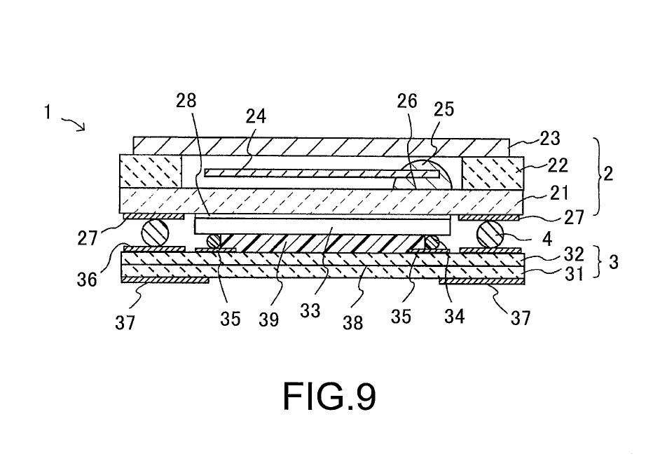

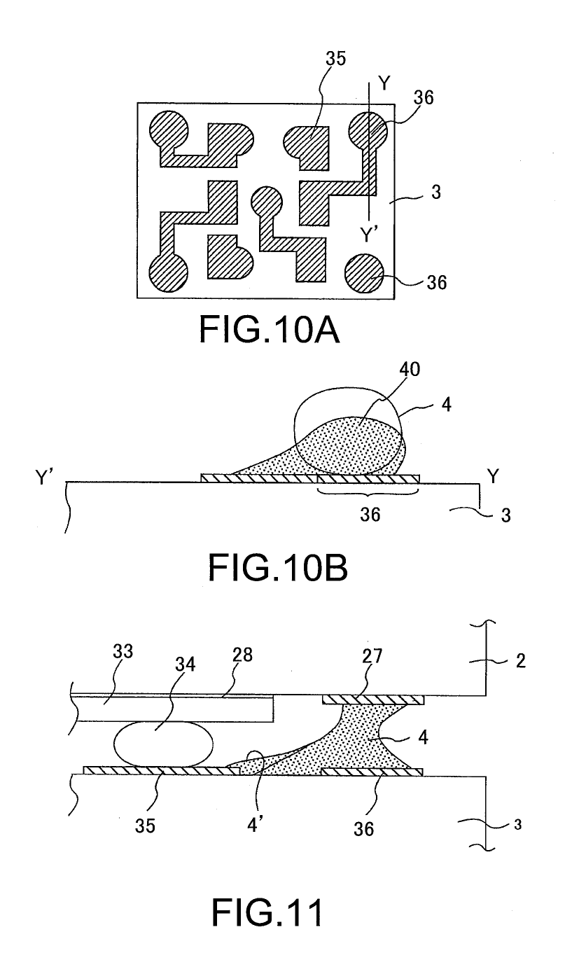

FIGS. 8A to 8C are plan views illustrating an exemplary arrangement of the intermediate layer, the connecting terminal and the electrode pad on one principal surface of the mounting board according to Embodiment 3 disclosed here. Embodiment 3 is also a modification of Embodiment 2. Embodiment 3 includes the intermediate layer 50 at wiring pattern side connected to electrode pads that are the electrode pads 35 in the mounting board 3 to place solder balls 4 excluding the single electrode pad, that is, connecting terminals 36-1, 36-2, and 36-4, which are connected to the wiring pattern except an connecting terminal 36-3 at the bottom right of FIG. 8A.

The intermediate layer 50 employs ceramic slurry so as to form openings 51 in FIG. 8B by screen-printing with a printing mask 60. Alternatively, the intermediate layer 50 is formed using a dispenser as needed. Then, the mounting board 3 is co-fired with the intermediate layer 50.

As illustrated in FIG. 8C, the intermediate layer 50 is disposed at the side that is connected to the wiring pattern of the connecting terminals 36-1, 36-2, and 36-4 with shapes connected to the wiring pattern. This positions a solder ball on the connecting terminal in the predetermined center position. This prevents the melted solder from wetting and flowing to the wiring pattern when the solder ball is melted in the reflow process, and prevents the interference to the adjacent other wiring patterns or electrode pads 35, thus reducing short-circuit failure of the product.

Accordingly, the solder balls 4 corresponding to the connecting terminals 36-1, 36-2, and 36-4 are placed in the respective centers of these connecting terminals, melted, and hardened, similarly to solder ball 4 corresponding to the connecting terminal 36-3 which is formed alone. Then, the solder balls 4 uniformly form the solder fillets in fine shapes between all terminals 27 of the crystal unit and the respective connecting terminals 36-1, 36-2, 36-3, and 36-4 of the mounting board 3. This ensures uniform and strong connection between the crystal unit 2 and the mounting board 3, thus providing the piezoelectricity oscillator such as the crystal controlled oscillator with high reliability.

The intermediate layer 50 in FIG. 8C may be formed by a method other than printing. For example, the intermediate layer may be formed as follows. Chip-like materials, which are cut out from a predetermined ceramic sheet, are placed at wiring pattern sides of the connecting terminals 36-1, 36-2, and 36-4 with shapes connected to the wiring patterns, and are then co-fired with the mounting board 3.

In each embodiment above, the IC chip 33 is secured to the electrode pads 35 at its mounting bumps 34 (gold bumps or the like) by ultrasonic thermo-compression bonding. Further, an adhesive layer or an underfill layer, which are preferred to be an epoxy resin, may be filled between the IC chip 33 and the mounting board 3. It is preferred that adhesive such as epoxy resin bond the second principal surface of the crystal unit 2 to the IC chip 33 as illustrated in FIGS. 8A to 8C.

This disclosure is not limited to mounting of a piezoelectric resonator such as the crystal unit on the mounting board as described in each embodiment. For example, the present invention is similarly applicable to mounting of composite parts such as a SAW filter.

In the case where the intermediate layer 5 employs a ceramic plate, the ceramic plate is disposed on one principal surface of the mounting board. The ceramic plate has a thickness thinner than a void between the crystal unit and the mounting board of the product. The ceramic plate has a plurality of solder ball placement openings in a position respectively corresponding to a position of each of the connecting terminals in the mounting board 3, and also has an IC chip mounting opening corresponding to a bump area for mounting the IC chip. The ceramic plate is integrally co-fired with the mounting board. The mounting board is preferred to include a metal film (which is made of copper, tungsten, and similar material) as a ground layer that is an electromagnetic shielding layer between the plurality of ceramic sheets and electromagnetically shields from the outside.

In the case where the intermediate layer 5 employs ceramic paste, the ceramic paste is assumed to be slurry with appropriate viscosity where fine particles of ceramic material similar to that of the mounting board 3 are dispersed in a dispersion medium. The ceramic paste is coated by a method using screen-printing or a dispenser so as to form the solder ball placement opening and the opening (an IC chip mounting opening) corresponding to the bump area for mounting the IC chip, similarly to the above method. The intermediate layer 5 is co-fired with the mounting board. This intermediate layer 5 is otherwise similar to the intermediate layer using the ceramic plate as described above.

A plurality of solder ball placement openings in the intermediate layer controls positions of a plurality of solder balls in respective predetermined positions. This uniformly forms the solder fillet in a fine shape between the terminals of the crystal unit and the connecting terminals of the mounting board after the respective solder balls are temporarily secured, melted to be secured in the reflow process, and then hardened. This prevents the melted solder from flowing outside of the connecting terminals in the mounting board, and prevents the interference to the adjacent other wiring patterns or electrode pads, thus considerably reducing short-circuit failure of the product. This ensures the uniform and strong connection between the crystal unit and the mounting board, thus providing the piezoelectricity oscillator such as the crystal controlled oscillator with high reliability.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A surface mount piezoelectric oscillator comprising:
a piezoelectric resonator;
a mounting board; and
an IC chip mounted on the mounting board, an oscillator circuit including the IC chip and the piezoelectric resonator, the piezoelectric resonator being bonded to the mounting board with a plurality of solder balls, wherein
the piezoelectric resonator includes a container main body, the container main body includes a bottom wall layer and a frame wall layer, a first principal surface of the bottom wall layer is laminated to form the frame wall layer and a recess is formed, the recess accommodates a piezoelectric oscillation piece, a lid body hermetically seals an opening end of the recess, the bottom wall layer of the container main body has a plurality of terminals on a second principal surface, the terminals are connected to the mounting board,
the mounting board consists of a ceramic plate, the mounting board includes a plurality of connecting terminals and a wiring pattern on one mounting board principal surface of the mounting board, the one mounting board principal surface faces the piezoelectric resonator of the mounting board, the connecting terminals are connected to the terminals of the piezoelectric resonator by melting and hardening the solder balls, the wiring pattern includes a plurality of electrode pads, the electrode pads are connected to a plurality of mounting bumps of the IC chip,
the mounting board includes an intermediate layer on the one mounting board principal surface, the intermediate layer is integrally formed with the mounting board, the intermediate layer includes:
a plurality of solder ball placement openings to position the solder balls in a center of each of the connecting terminals; and
an IC chip mounting opening to mount the IC chip, wherein
the mounting board includes a plurality of surface mount terminals on another mounting board principal surface, the surface mount terminals are for mounting an electronic device thereon.

2. The surface mount piezoelectric oscillator according to claim 1, wherein
the intermediate layer is the mounting board being co-fired and integrally formed with a board in which the board includes a ceramic plate made of a same material with the mounting board and the solder ball placement openings and the IC chip mounting opening are formed thereon.

3. The surface mount piezoelectric oscillator according to claim 1, wherein
the intermediate layer is the mounting board being co-fired and coated with a ceramic paste, in which fine particles of a ceramic material which is a same material with the mounting board are dispersed in the ceramic paste, and the solder ball placement openings and the IC chip mounting opening of the another mounting board principal surface of the mounting board are formed thereon.

4. The surface mount piezoelectric oscillator according to claim 1, wherein
a solder fillet is formed by melting and hardening each of the solder balls connected to the terminals of the piezoelectric resonator and the connecting terminals of the mounting board, and the solder fillet has an approximately uniform drum-shaped appearance.

5. The surface mount piezoelectric oscillator according to claim 1, wherein
the piezoelectric resonator includes a crystal unit.
